(19) United States
(12) Patent Application Publication
(10) Pub. No.: US 2008/0048223 A1
(43) Pub. Date: Feb. 28, 2008

(54) CMOS IMAGE SENSOR AND METHOD OF FABRICATING THE SAME

(76) Inventor: In-Guen Yeo, Gwangju (KR)

Correspondence Address: SHERR & NOURSE, PLLC, 620 HERNDON PARKWAY, SUITE 200, HERNDON, VA, 20170, US

(21) Appl. No.: 11/844,705

(22) Filed: Aug. 24, 2007

(30) Foreign Application Priority Data
Aug. 28, 2006 (KR) 10-2006-0081963

(51) Int. Cl. H01L 31/062; H01L 21/00

(52) U.S. Cl. 257/292; 438/70; 257/E31.001

(57) ABSTRACT

A CMOS image sensor and a fabricating method thereof improves sensitivity to blue light by forming a depletion layer by means of a PN junction in a gate of a drive transistor. The depletion layer formed on the upper portion of the gate improves the sensitivity of the CMOS image sensor to blue light.

The present application claims priority under 35 U.S.C. 119 to Korean Patent Application No. 10-2006-0081963, filed Aug. 28, 2006, which is hereby incorporated by reference in its entirety.

### BACKGROUND

Image sensors have been widely applied to various fields such as machine vision, robotics, satellite related apparatus, cars, navigation, guidance, cellular phones, etc. Generally, in image sensors, a plurality of pixels forming an image frame are two-dimensionally arranged.

Briefly describing the principles of image sensors, light energy reflected from a subject is first absorbed by means of an optoelectronic converter and then electrons are generated by a photoelectric effect. The generated electrons are proportional to the amount of light absorbed and are accumulated in an optoelectronic converter formed on a semiconductor substrate and are then read by a read-out operation.

As an example, a photo diode may be used as the optoelectronic converter, and more than three or four transistors can be used in a unit pixel of an image sensor. Hereinafter, a circuit of a CMOS image sensor having three transistors will be described with reference to the accompanying drawings.

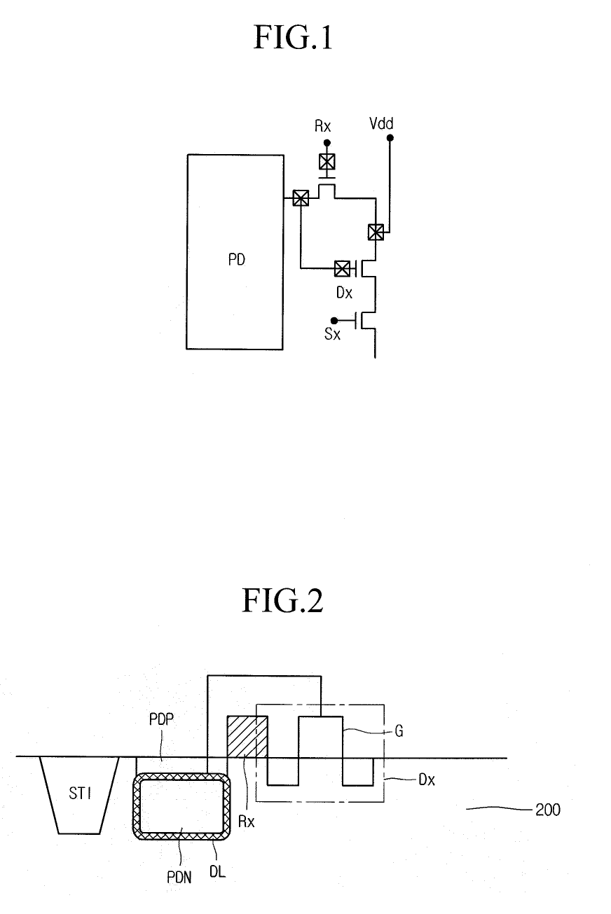

Example FIG. 1 is a circuit diagram of a CMOS image sensor having three transistors. A CMOS image sensor comprises a photo diode (PD), a reset transistor (Rx), a drive transistor (Dx), and a select transistor (Sx). Since the photo diode is connected to the gate of the drive transistor Dx that performs a role of a source follower, it can be appreciated that the potential of the gate is the same as that of the photo diode PD.

Example FIG. 2 is cross-sectional view of an image sensor having three transistors. Referring to example FIG. 2, an N type photo diode (PDN) isolated by means of a shallow trench isolation (STI) and doped with N type impurity is formed on a semiconductor substrate 200 in a pixel region doped with P type impurity. A photo diode P type (PDP) formed by ion-implanting P type impurity again is formed on the upper part of the photo diode N type (PDN). Also, the photo diode is connected to the gate (G) of the drive transistor Dx through a metal wiring.

The photo diode comprises a depletion layer (DL) formed in a region where the PDP contacts the PDN by means of a PN junction. The depletion layer (DL) is expanded inside and outside the PDN according to a reverse bias applied from an external source. When the light corresponding to an actual image is irradiated, the depletion layer (DL) leads to a photoelectric reaction with the irradiated light to generate electrons.

As described above, the amount of electrons generated from the depletion layer (DL) by reacting with the irradiated light determines the sensitivity, or sensing ability, of the image sensor to the light. Therefore, the volume of the depletion layer (DL) generating electrons corresponding to the irradiated light is an important factor in determining the sensitivity of the image sensor.

In particular, in the case of blue light, since it does not enter deeply inside the substrate as compared to green light or red light, forming a large size depletion layer near a surface is beneficial in a multi-primary color image sensor.

However, because improving integration of such devices is also desirable, it is undesirable to increase the structure of the photo diode including the depletion layer or to increase the depletion layer (DL) by means of changing the structure of the photo diode.

### SUMMARY

Embodiments relate to a method for improving the blue/green ration of a CMOS image sensor. In accordance with this method a gate is formed on an active region of a conductive semiconductor substrate and a photo diode is also formed on the active region. A depletion layer is then formed in the gate; and the photo diode and the gate are electrically connected

Embodiments relate to an apparatus that includes a conductive semiconductor substrate having an active region; a photo diode formed on the active region; and a depletion layer formed on the active region and electrically connected to the photo diode. Furthermore, the depletion layer includes a first conductive impurity doped layer, a second conductive impurity doped layer; and a junction portion between the first conductive impurity doped layer and the second conductive impurity doped layer.

Embodiments relate to a method that includes a) forming a gate on an active region of a conductive semiconductor substrate; b) forming a photo diode on the active region; c) forming a depletion layer in the gate; and d) electrically connecting the photo diode and the gate.

### DRAWINGS

Example FIG. 1 is a circuit diagram of an image sensor showing a CMOS image sensor.

Example FIG. 2 is a cross-sectional view of the CMOS image sensor.

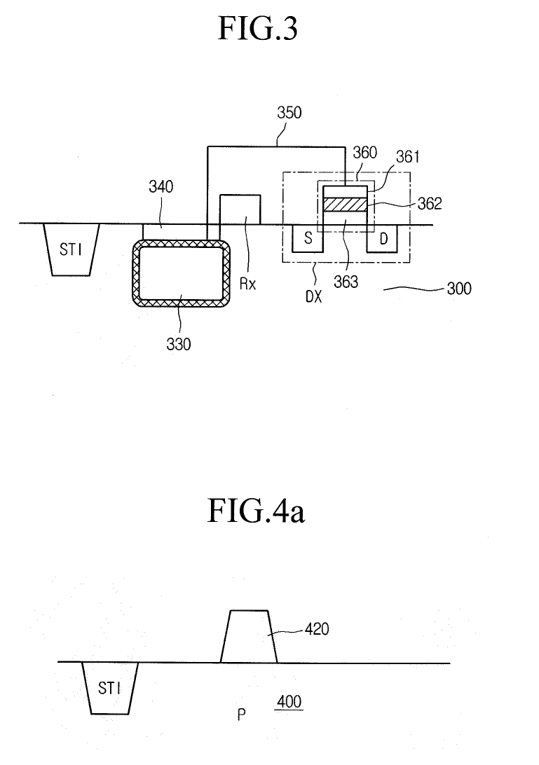

Example FIG. 3 is a cross-sectional view of a CMOS image sensor, according to embodiments.

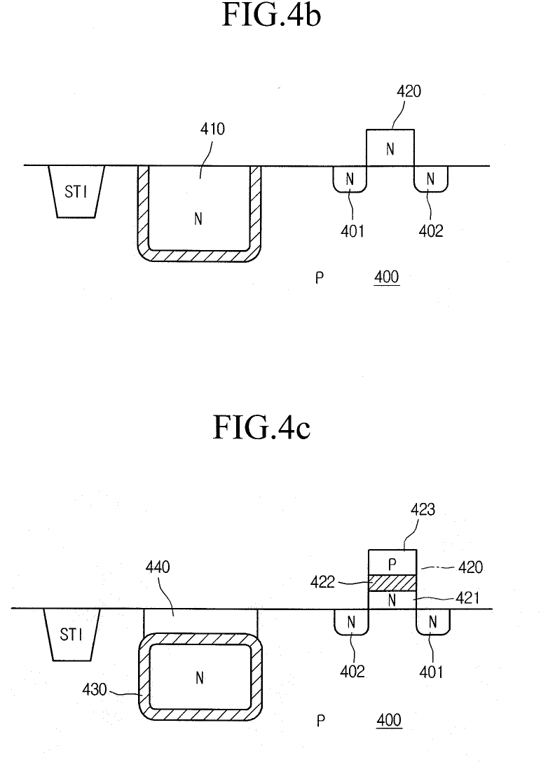

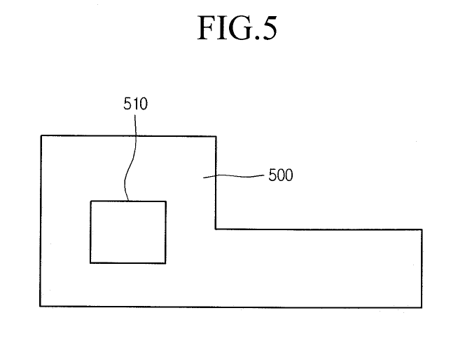

Example FIGS. 4a to 4c are cross-sectional views showing a fabricating process of a CMOS image sensor, according to embodiments.

Example FIG. 5 is a plan view of a gate of a driver transistor in the CMOS image sensor, according to embodiments.

### DETAILED DESCRIPTION

Example FIG. 3 is a cross-sectional view showing a CMOS image sensor having a structure of three transistors according to embodiments described herein.

Referring to example FIG. 3, the CMOS image sensor comprises a PDN region 330 formed on a P type semiconductor substrate 300 formed by being doped with P type impurity. Also, a PDP region 340 including P type impurity is provided on the PDN 330.

As described in example FIG. 1, the photo diode 330 in the CMOS image sensor having the three transistors is connected to a gate 360 of a drive transistor (DX) through a metal wiring 350. Also, the inside of the gate 360 is provided with a depletion layer 362 by means of a PN junction between a P type region 361 in the upper portion thereof and a N type region 363 in the lower portion thereof.

In the case of a multi-primary image sensor, it uses three different color lights such as green, blue, and red; because the lights have different wavelengths the thickness of the each depletion layer that generates a photoelectric effect for each color is different.

For example, the depth of half absorption for the green light is about 0.79 μm, for the blue light it is about 0.01 μm, and for the red light it is about 3.0 μm. Thus, the blue light has the shortest depth of half absorption. Therefore, the blue light among the three lights generates photocharge by a photoelectric reaction with the depletion layer with the shallowest thickness.

One numerical value used to indicate the sensitivity, or sensing ability, of an image sensor using the characteristics of the blue light is a blue/green ratio (B/G). The higher the B/G ratio becomes, the better the reactivity of the image sensor is to blue light.

When blue light is irradiated on the depletion layer, if more electrons are generated in the depletion layer of a unit pixel, then the better the reactivity of the image sensor is to the generated electrons. As a result, the B/G ratio is also higher.

In the operation of a unit pixel of the CMOS image sensor, when the blue light enters the unit pixel of the image sensor, the photo diode as well as the depletion layer 362 of the gate 360 generates electrons according to the photoelectric effect.

Thereafter, the electrons generated by means of the depletion layer 362 are coupled, through the metal wiring 350, with the electrons generated from the photo diode which react with the blue light to increase the amount of electrons generated in the unit pixel, thereby increasing the B/G ratio.

A fabricating process of a CMOS image sensor according embodiments is described in detail with reference to the following drawings. Example FIGS. 4a to 4d are views showing a fabricating method of an image sensor, according to embodiments.

Referring to example FIG. 4a, a device isolating region (STI) defining an active region and a field region is formed on a P type semiconductor substrate. Then, a gate 420 for a drive transistor is formed on a predetermined active region of the P type semiconductor substrate. The reset transistor and select transistor are not shown for convenience of explanation and the description thereof is omitted. Generally, in the fabricating process of the CMOS image sensor having the three transistors, the gate 420 is formed and so that the photo diode forming process can continue. The gate 420 is formed by a process that stacks a gate oxide film (not shown) and stacks and patterns a polysilicon on the gate oxide film and then dopes with an N type impurity.

Referring to example FIG. 4b, a PDN 410 and the gate 420 are formed by doping an N type impurity on the predetermined active region of the semiconductor substrate. Thereafter, a source 401 and a drain 402 are formed by implanting an N type impurity on the semiconductor substrate adjacent both sides of the gate 420.

Referring to example FIG. 4c, in order to improve the sensitivity of the image sensor, a PDP 440 is formed by doping a P type impurity on the PDN 410.

Also, the gate 420 is ion-implanted with a P type impurity. Accordingly, the upper portion of the gate 420 implanted with an N type impurity has a P type structure 423 so that the inside of the gate 420 is provided with a depletion layer 422 by means of a PN junction between a P type structure 423 of the upper portion and a N type structure 421 of the lower portion.

The process 440 of forming the P type photo diode and the process of forming the depletion layer 422 of the gate 420 can be performed by a single ion implanting process or multiple, separate ion implanting processes.

After performing the process, the gate 420 of the drive transistor is connected to the photo diode such as, for example, through the metal wiring 350 as shown in example FIG. 3. Thus, the electrons generated from the depletion layer of the gate 420 are coupled with the electrons generated from the photo diode. Thereby, the sensitivity of the image sensor to blue light is increased so that the B/G ratio is increased.

According to embodiments described herein, in the process of ion-implanting the P type impurity into the gate 420 of the drive transistor is not performed over the entire region of the gate 420. As a result, some region of the overall cross section of the gate is not formed with the depletion layer 422 inside.

Example FIG. 5 is a plan view of the depletion layer inside the gate of the drive transistor in the CMOS image sensor according to embodiments described herein.

Referring to example FIG. 5, a portion 510 of the overall surface 500 of the gate is not formed with the depletion layer.

The region 510 where the depletion layer is not formed is later formed with a contact (not shown) for the gate. The electrical contact of the second conductive region of the lower portion of the gate and other devices of the semiconductor substrate is made through this contact.

The CMOS image sensor according to embodiments as described above increases an area of the depletion layer reacting with blue light as compared to the image sensor of the related art. Accordingly, the reactivity to the blue light is increased, making it possible to increase the B/G ratio.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a conductive semiconductor substrate having an active region;
a photo diode formed on the active region; and
a depletion layer formed on the active region and electrically connected to the photo diode, the depletion layer comprising:
a first conductive impurity doped layer,
a second conductive impurity doped layer; and
a junction portion between the first conductive impurity doped layer and the second conductive impurity doped layer.

2. The apparatus of claim 1, further comprising a device isolating region defining the active region.

3. The apparatus of claim 1, wherein the apparatus is a CMOS image sensor.

4. The apparatus of claim 1, wherein the first conductive impurity doped layer is positioned above the second conductive impurity doped layer.

5. The apparatus of claim 1, wherein approximately all of first conductive impurity doped layer is doped.

6. The apparatus of claim 1, wherein a first portion of the first conductive doped layer is doped and a second portion of the first conductive doped layer is undoped.

7. The apparatus of claim 6, further comprising a contact part formed through the second portion.

8. The apparatus of claim 1, wherein the first conductive doped layer is a P type.

9. The apparatus of claim 1, wherein the second conductive doped layer is an N type.

10. A method comprising:
forming a gate on an active region of a conductive semiconductor substrate;
forming a photo diode on the active region;
forming a depletion layer in the gate; and
electrically connecting the photo diode and the gate.

11. The method of claim 10, wherein forming a photo diode further comprises:
forming a second conductive photo diode region by ion-implanting a second conductive impurity into the active region; and
forming a first photo diode conductive region in the second conductive photo diode region, wherein the first photo diode conductive region is of a first conductive impurity.

12. The method of claim 10, wherein forming the depletion layer further comprises:
ion-implanting a first conductive impurity into the gate; and
ion-implanting a second conductive impurity into the gate.

13. The method of claim 12, wherein forming a photo diode further comprises:
forming a second conductive photo diode region by ion-implanting the second conductive impurity into the active region; and
forming a first photo diode conductive region in the second conductive photo diode region, wherein the first photo diode conductive region is of the first conductive impurity.

14. The method according to claim 13, wherein ion implanting the first conductive impurity into the gate and forming the first conductive photo diode region are performed at the same time.

15. The method of claim 10, wherein the depletion layer is formed such that the depletion layer does not extend across the entire gate.

16. The method of claim 11, wherein the first conductive impurity is a P type and the second conductive impurity is an N type.

17. The method of claim 12, wherein the first conductive impurity is a P type and the second conducting impurity is an N type.

18. A method for improving the blue/green ration of a CMOS image sensor, comprising:
forming a gate on an active region of a conductive semiconductor substrate;
forming a photo diode on the active region;
forming a depletion layer in the gate; and
electrically connecting the photo diode and the gate.

19. The method of claim 18, wherein forming the depletion layer further comprises:
ion-implanting a first conductive impurity into the gate; and
ion-implanting a second conductive impurity into the gate.

20. The method of claim 19, wherein forming a photo diode further comprises:
forming a second conductive photo diode region by ion-implanting the second conductive impurity into the active region; and
forming a first photo diode conductive region in the second conductive photo diode region, wherein the first photo diode conductive region is of the first conductive impurity.
